(19) United States
(12) Patent Application Publication
(10) Pub. No.: US 2026/0126692 A1
(43) Pub. Date: May 7, 2026

(54) ARRAY SUBSTRATE, DISPLAY PANEL AND DISPLAY DEVICE

(71) Applicants: CHENGDU BOE DISPLAY SCI-TECH CO., LTD., Sichuan (CN); BOE Technology Group Co., Ltd., Beijing (CN)

(72) Inventors: Guozhi WANG, Beijing (CN); Yuanhui GUO, Beijing (CN); Yong LIU, Beijing (CN); Wu WANG, Beijing (CN)

(21) Appl. No.: 18/706,289

(22) PCT Filed: Mar. 29, 2023
(86) PCT No.: PCT/CN2023/084610

§ 371 Date: Apr. 30, 2024

(51) Int. Cl. G02F 1/1362; H10D 86/40

(52) U.S. Cl. CPC G02F 1/136286; G02F 1/136209; H10D 86/441

(57) ABSTRACT

Disclosed are an array substrate, display panel, and display device; the array substrate includes: gate line groups, data lines, pixel electrodes, and the pixel electrodes includes: a first-type pixel electrode, and a second type pixel electrode, a light-shielding portion is on the same side of the substrate as the gate line group and is only in the area where the first type of pixel electrode is located, and the light-shielding portion includes: a first portion extending in the first direction, an orthographic projection of the first portion on the substrate passes through a central area of an orthographic projection of the first-type pixel electrode on the substrate.

### CROSS-REFERENCE TO RELATED APPLICATIONS

The application is a National Stage of International Application No.

PCT/CN2023/084610, filed Mar. 29, 2023, which is hereby incorporated by reference in its entirety.

### TECHNICAL FIELD

The present disclosure relates to the field of semiconductor technology, in particular to an array substrate, a display panel and a display device.

### BACKGROUND

Thin Film Transistor-Liquid Crystal Display (TFT-LCD) has a variety of commonly used display modes, such as Twisted Nematic (TN) display mode, Vertically Alignment (VA) display mode, and Fringe Field Switching (FFS) display mode, as well as In-Plane Switching (IPS) display mode, etc. The VA mode has the advantages of better dark performance and better contrast compared with other display modes.

### SUMMARY

Embodiments of the present disclosure provide an array substrate, including:
a substrate;
a plurality of gate line groups on a side of the substrate, and the plurality of gate line groups extend along a first direction;
a plurality of data lines on the same side of the substrate as the gate line groups; the plurality of data lines extend along a second direction;
a plurality of pixel electrodes on the same side of the substrate as the gate line groups, and in an area formed by an intersection of the gate line groups and the data lines, each of the plurality of pixel electrodes includes: a first-type pixel electrode and a second-type pixel electrode;
a light-shielding portion on the same side of the substrate as the gate line groups, and only in an area where the first-type pixel electrode is located; the light-shielding portion includes: a first portion extending in the first direction; an orthographic projection of the first portion on the substrate passes through a central area of an orthographic projection of the first-type pixel electrode on the substrate.

In some embodiments, the light-shielding portion further includes: a second portion that is on a side of the first portion and extends along the second direction;
the second portion is connected with one end of the first portion, and an orthotropic projection of the second portion on the substrate overlaps with an orthographic projection of a side area of the first-type of pixel electrode on the substrate.

In some embodiments, the light-shielding portion further includes: a third portion that is on the other side of the first portion and extends along the second direction;
the third portion is connected with the other end of the first portion, and an orthotropic projection of the third portion on the substrate overlaps with an orthographic projection of the other side area of the first-type pixel electrode on the substrate.

In some embodiments, the first-type pixel electrode is a pixel electrode corresponding to a blue color resistance, and the second-type of pixel electrode includes a pixel electrode corresponding to a red color resistance, or a pixel electrode corresponding to a green color resistance.

In some embodiments, the array substrate further includes: a first signal wiring layer, and the light-shielding portion and the first signal wiring layer are on a same layer and of a same material.

In some embodiments, the first signal wiring layer further includes: a first common electrode wiring group extending along the second direction, and the first common electrode wiring group is disconnected at the gate line groups;
the first common electrode wiring group includes: two first common electrode wires extending along the second direction at different sides of each data line, and the light-shielding portion and the first common electrode wire close to the first-type pixel electrode in the first common electrode wiring group are integrated connection structure.

In some embodiments, a width of the second portion in the first direction is 1˜3 times a width of the first common electrode wire in the first direction.

In some embodiments, a width of the third portion in the first direction is approximately equal to a width of the second portion in the first direction.

In some embodiments, a width of the first portion in the second direction is approximately equal to a width of the second portion in the first direction.

In some embodiments, the first signal wiring layer further includes: a second common electrode wire extending along the first direction; a pixel electrode is provided between the second common electrode wire and the gate line group, and the second common electrode wire in a same extension direction is an integrated connection structure;
there is a gap between the second portion and the second common electrode wire, and the first common electrode wire, the second common electrode wire, and the second portion form a first notch with an opening facing a side of the first-type pixel electrode.

In some embodiments, each gate line group includes: a primary gate line and a secondary gate line; the first signal wiring layer further includes: a third common electrode wire that is arranged at a side of the secondary gate line far away from the primary gate line, and extends along the first direction; there is the pixel electrode between the third common electrode wire and the second common electrode wire, and the third common electrode wire in a same extension direction is disconnected in an area where the data line is located;
there is a gap between the third portion and the third common electrode wire, and the first common electrode wire, the third common electrode wire, and the third portion form a second notch with an opening facing a side of the pixel electrode.

In some embodiments, the third common electrode wire includes: a first subsection and a second subsection located on a side of the first subsection far away from the second notch; a width of the first subsection in the second direction is greater than a width of the second subsection in the second direction.

In some embodiments, the first signal wiring layer further includes: a fourth common electrode wire that is arranged on a side of the primary gate line far away from the secondary gate line, and extends along the first direction; there is the pixel electrode between the fourth common electrode wire and the second common electrode wire, and the fourth common electrode wire in a same extension direction is disconnected in an area where the data line is located;
the array substrate further includes a first transistor connected with the data line and arranged on a side of the data line;
the fourth common electrode wire includes a notch group, the notch group includes: a first notch located on a side of one data line, and a third notch located on the other side of the one data line and including an opening facing a side of the primary gate line, and the first notch and the first transistor are located on a same side of the one data line.

In some embodiments, the plurality of pixel electrodes includes: a first pixel electrode row and a second pixel electrode row which extend along the first direction and are alternately arranged along the second direction; the first pixel electrode row is arranged on a side of the primary gate line far away from the secondary gate line, and the second pixel electrode row is arranged on a side of the secondary gate line far away from the primary gate line;
the first pixel electrode row includes a plurality of first pixel electrodes, and the second pixel electrode row includes a plurality of second pixel electrodes.

In some embodiments, the layer where the data line is located further includes: a first electrode of the first transistor electrically connected with the data line, and a first electrode portion arranged on a side of the first electrode of the first transistor;
the first electrode portion includes: a second electrode of the first transistor, a first lap portion electrically connected with the second electrode of the first transistor, and a second lap portion extending along the first direction from one end of the first lap portion;
an orthographic projection of the first lap portion on the substrate overlaps with an orthographic projection of the first pixel electrode on the substrate, the first lap portion is electrically connected with the first pixel electrode through a first through hole, and an orthotropic projection of the second lap portion on the substrate overlaps with an orthographic projection of the fourth common electrode wire on the substrate to form a first capacitance.

In some embodiments, a maximum width of the first lap portion in the second direction is greater than a maximum width of the second lap portion in the second direction.

In some embodiments, the layer where the data line is located further includes: a second electrode portion arranged on the other side of the first electrode of the first transistor;
the second electrode portion includes: a third electrode of the first transistor, a third lap portion, a first-transistor connection portion connecting the third electrode of the first transistor and the third lap portion, and a fourth lap portion extending along the first direction from one end of the third lap portion;
an orthographic projection of the third lap portion on the substrate overlaps with an orthotropic projection of the second pixel electrode on the substrate, the third lap portion is electrically connected with the second pixel electrode through a second through hole; an orthotropic projection of the fourth lap portion on the substrate overlaps with an orthographic projection of the third common electrode wire on the substrate to form a second capacitance.

In some embodiments, a maximum width of the third lap portion in the second direction is greater than a maximum width of the fourth lap portion in the second direction.

In some embodiments, the layer where the data line is located further includes: a third electrode portion arranged on a side of the second electrode portion facing the gate line group;
the third electrode portion includes: a second electrode of the second transistor and a fifth lap portion connected with the second electrode of the second transistor; an orthographic projection of the fifth lap portion on the substrate overlaps with the orthographic projection of the third common electrode wire on the substrate to form a third capacitance.

In some embodiments, a maximum width of the fifth lap part in the second direction is greater than a maximum width of the second electrode of the second transistor in the second direction.

In some embodiments, the orthographic projection of the fifth lap portion on the substrate does not overlap with the orthographic projection of the fourth lap portion on the substrate.

In some embodiments, the first transistor includes: a control electrode of the first transistor, an active layer of the first transistor, the first electrode of the first transistor, the second electrode of the first transistor and the third electrode of the first transistor; wherein the control electrode of the first transistor is a portion of the primary gate line.

In some embodiments, the array substrate further includes: a second transistor;
the second transistor includes: a control electrode of the second transistor, an active layer of the second transistor, a first electrode of the second transistor, the second electrode of the second transistor; wherein the control electrode of the second transistor is a portion of the secondary gate line, the first-transistor connection portion is multiplexed as the first electrode of the second transistor.

In some embodiments, the array substrate further includes an active layer and a passivation layer covering a side of the active layer far away from the substrate; the active layer includes the active layer of the first transistor and the active layer of the second transistor;
a material of the active layer includes indium gallium zinc oxide, and a material of the passivation layer includes silicon dioxide and silicon nitride.

In some embodiments, the array substrate further includes: a first wiring, a second wiring, and an adapter portion;
there is a first insulating layer between the adapter portion and the first wiring, the first insulating layer includes a third through hole; the third through hole exposes a part of the first wiring, and exposes a part of the substrate;
there is a second insulating layer between the adapter portion and the second wiring, the second insulating layer includes a fourth through hole; the fourth through hole exposes a part of the second wiring, and exposes a part of the substrate;
one end of the adapter portion covers the third through hole, and contacts with the first wiring through the third through hole; the other end of the adapter portion covers the fourth through hole, and contacts with the second wiring through the fourth through hole; the adapter portion laps the first wiring with the second wiring.

In some embodiments, the first wirings include the primary gate line, the secondary gate line, the data line, the first common electrode wire, the second common electrode wire, the third common electrode wire or the fourth common electrode wire;
the second wire trace includes: the primary gate line, the secondary gate line, the data line, the first common electrode wire, the second common electrode wire, the third common electrode wire or the fourth common electrode wire.

In some embodiments, the adapter portion and the pixel electrode are on a same layer and of same material.

In some embodiments, the first insulating layer includes a gate insulating layer, a passivation layer, and/or a planarization layer; the second insulating layer includes an insulating layer, a passivation layer, and/or a planarization layer.

Embodiments of the present disclosure provide an array substrate, including:
a substrate;
a plurality of gate lines on a side of the substrate, and extending in a first direction;
a plurality of data lines on the same side of the substrate as the gate lines, and extending along a second direction;
a plurality of pixel electrodes on the same side of the substrate as the gate lines, and in an area formed by an intersection of the gate lines and the data lines;
where each data line includes a first data portion extending in the second direction, a second data portion extending in the second direction, and a third data portion extending along the first direction and connecting the first data portion with the second data portion; an extension line of the first data portion does not overlaps with an extension line of the second data portion; an orthographic projection of an extension line of the third data portion on the substrate passes through a central area of an orthographic projection of the pixel electrode on the substrate; an orthographic projection of the first data portion on the substrate overlaps with an orthographic projection of a first side area of the pixel electrode on the substrate; an orthotropic projection of the second data portion on the substrate overlaps with an orthographic projection of a second side area of the pixel electrode on the substrate.

In some embodiments, a length of the third data portion in the first direction is 2-4 times a width of the first data portion in the first direction.

In some embodiments, the array substrate further includes: a second electrode of a transistor in a layer same as a layer where the data lines are located, and a first electrode block connected with the second electrode of the transistor;
the first electrode block is arranged at a position between two adjacent third data portions; an orthographic projection of the first electrode block on the substrate overlaps with the orthographic projection of the pixel electrode on the substrate, and the first electrode block is electrically connected with the pixel electrode through a fifth through hole.

In some embodiments, the array substrate further includes: a fifth common electrode wiring group; the fifth common electrode group includes: two fifth common electrode wire extending along the first direction;
a second electrode block is provided between two fifth common electrode wires in a same fifth common electrode wiring group, and an orthotropic projection of the second electrode block on the substrate overlaps with an orthotropic projection of the first common electrode block on the substrate to form a fourth capacitance.

Embodiments of the present disclosure further provide a display panel, including the array substrate provided by embodiments of the present disclosure.

In some embodiments, the display panel further includes an opposing substrate opposite to the array substrate, and the opposing substrate is provided with a common electrode layer.

In some embodiments, the display panel further includes a liquid crystal layer arranged between the array substrate and the opposing substrate; the liquid crystal layer includes four liquid crystal regions in an area where the pixel electrodes are located, and liquid crystal orientations in the liquid crystal regions are different.

Embodiments of the present disclosure further provide a display device, including the display panel provided by embodiments of the present disclosure.

### BRIEF DESCRIPTION OF FIGURES

FIG. 1 is a schematic diagram of the principle of a pixel producing color shift.

FIG. 2A is one of the schematic diagrams of the array substrate provided by an embodiment of the present disclosure.

FIG. 2B is a schematic diagram of a single layer of a layer where the gate line group in FIG. 2A is located.

FIG. 2C is a schematic diagram of a single layer of an active layer in FIG. 2A.

FIG. 2D is a schematic diagram of a single layer of a data line layer in FIG. 2A.

FIG. 2E is a schematic diagram of a single layer of a pixel electrode layer in FIG. 2A.

FIG. 2F is a magnified schematic diagram of the middle left side of FIG. 2A.

FIG. 2G is a magnified schematic diagram of the middle right side in FIG. 2A.

FIG. 3 is a schematic diagram of processing disconnection of the data line and the second common electrode wire by cutting.

FIG. 4 is a schematic diagram of a circuit provided by an embodiment of the present disclosure.

FIG. 5A is a schematic diagram of a connection of different wires provided by an embodiment of the present disclosure.

FIG. 5B is a cross-sectional diagram along the dashed line AA′ in FIG. 5A.

FIG. 5C is a cross-sectional diagram along the dashed line BB′ in FIG. 5A.

FIG. 6 is a magnified schematic diagram of the dashed circle S of FIG. 2A.

FIG. 7 is a cross-sectional schematic diagram of the display panel provided by an embodiment of the present disclosure.

FIG. 8A is the second schematic diagram of the array substrate provided by an embodiment of the present disclosure.

FIG. 8B is a schematic diagram of a single layer of a gate line 20 in FIG. 8A.

FIG. 8C is a schematic diagram of a single layer the data line in FIG. 8A.

FIG. 8D is a schematic diagram of a single layer of the pixel electrode in FIG. 8A.

FIG. 9 is a schematic diagram of a liquid crystal with a plurality of orientation regions in the area where the same pixel electrode is located provided by an embodiment of the present disclosure.

### DETAILED DESCRIPTION

In order to make the purpose, technical solution and advantages of embodiments of the present disclosure clearer, the technical solutions of embodiments of the present disclosure will be clearly and completely described below in conjunction with the accompanying drawings of embodiments of the present disclosure. Obviously, embodiments described are some embodiments of the present disclosure, not all embodiments. Based on embodiments of the present disclosure described, all other embodiments obtained by a person skilled in the art without creative labor are within the scope of protection of the present disclosure.

Unless otherwise defined, the technical or scientific terms used in this disclosure shall have the ordinary meaning understood by persons with general skill in the field to which this disclosure belongs. The terms “first”, “second” and similar expressions used in this disclosure do not indicate any order, number or importance, but only to distinguish the different components. Words such as “include” or “comprise” mean that the element or object preceding the word includes the element or object listed after the word and its equivalents, and does not exclude other elements or objects. Similar terms such as “coupled” or “connected” are not limited to physical or mechanical connections, but may include electrical connections, whether direct or indirect. “Up”, “Down”, “Left”, “Right”, etc., are only used to indicate the relative positional relationship, and when the absolute position of the object being described changes, the relative positional relationship may also change accordingly.

As used herein, the words “approximately” or “substantially the same” include the stated values and imply an acceptable deviation from the specific values as determined by a person of ordinary skill in the art taking into account the measurements in question and the errors associated with the measurements of the specific quantities (i.e., the limitations of the measurement system). For example, “approximately the same” can mean that the difference from the stated value is within one or more standard deviations, or within the range of ±30%, 20%, 10%, or 5%.

In the drawings, the thickness of layers, films, panels, areas, etc., is enlarged for clarity. In the present disclosure, an exemplary embodiment is described with reference to a cross-sectional diagram that is a schematic diagram of an idealized embodiment. In this way, deviations from the shape of the diagram are expected as a result of, for example, manufacturing techniques and/or tolerances. Therefore, the embodiments described in this article should not be construed as being limited to the specific shape of the area shown herein, but rather as including deviations in the shape caused by, for example, manufacturing. For example, an area that is illustrated or described as flat can typically have rough and/or non-linear characteristics. In addition, the sharp corners shown can be round. Thus, the areas shown in the diagram are inherently schematic, and their shapes do not purport the exact shape of the illustrated areas and are not intended to limit the scope of the claims.

In order to keep the following descriptions of the embodiments of the present disclosure clear and concise, the detailed descriptions of known functions and known parts are omitted.

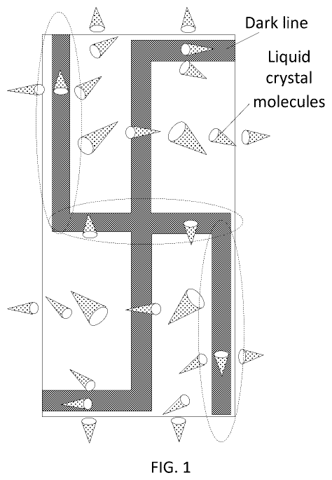

VN display products, after ultraviolet induced multi-domain vertical alignment, UV2A, as shown in FIG. 1, for the liquid crystal molecules under the dark lines in the center of the pixel and the dark lines on both branches (as shown in the black stripes in FIG. 1), when the human eye looks at the liquid crystal molecules from the side view angle, the liquid crystal molecules are viewed from the side of the long axis of the liquid crystal molecules, and due to the birefringence of the liquid crystal, the light leakage from the side angle of the UV2A alignment display mode occurs, and for the indium gallium zinc oxide, IGZO type transistors, since Si02 needs to be used in the gate insulation layer and passivation layer to protect IGZO, and the refractive index of SiO₂ in the gate insulation layer and passivation layer is different from that of SIN, resulting in purple by interference of transmitted light from the side view, and the color shift phenomenon appears, and the picture of the side view is blue.

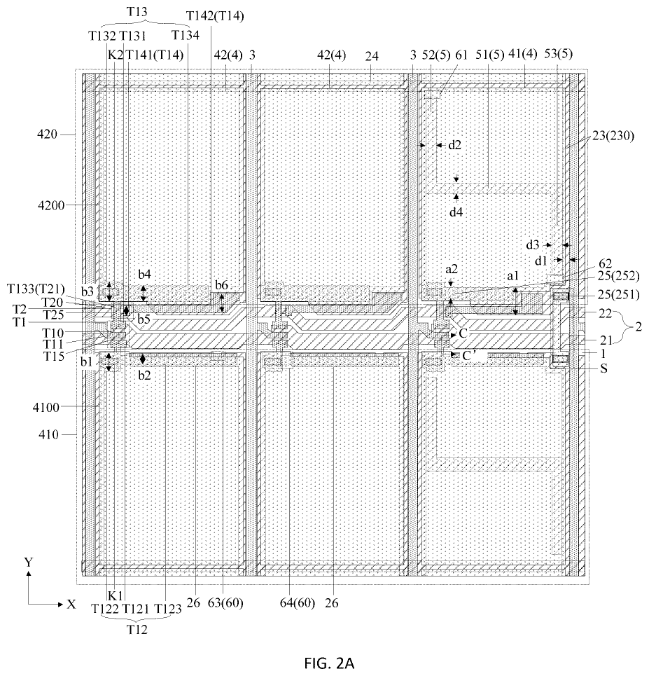

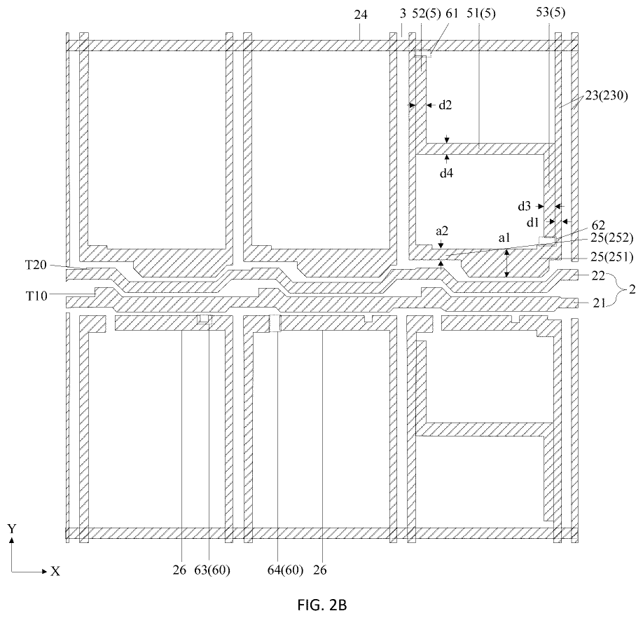

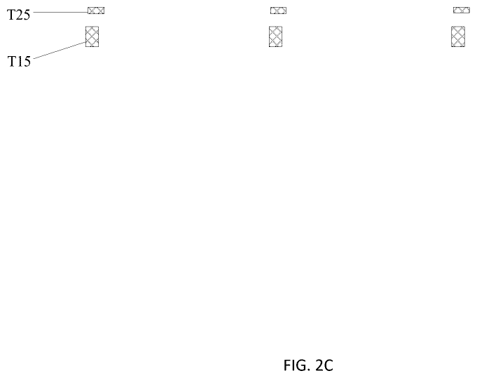

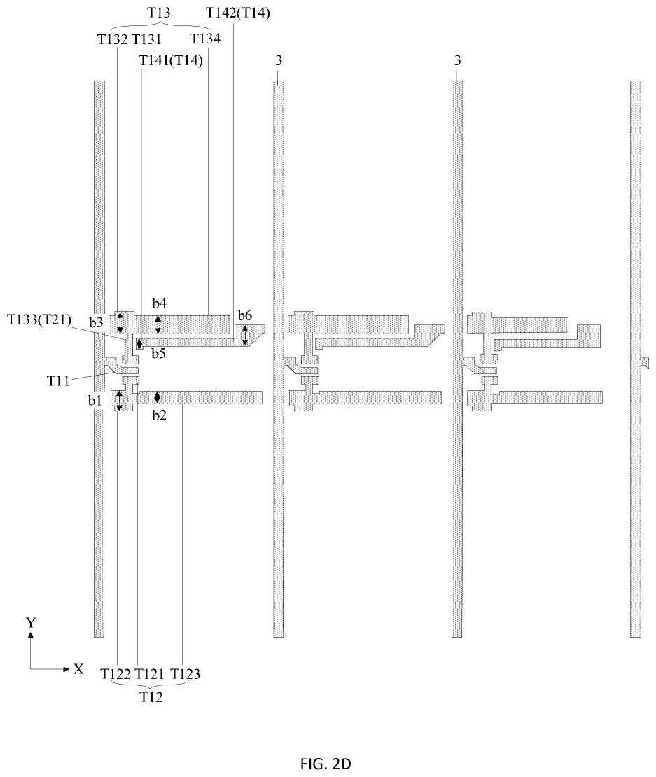

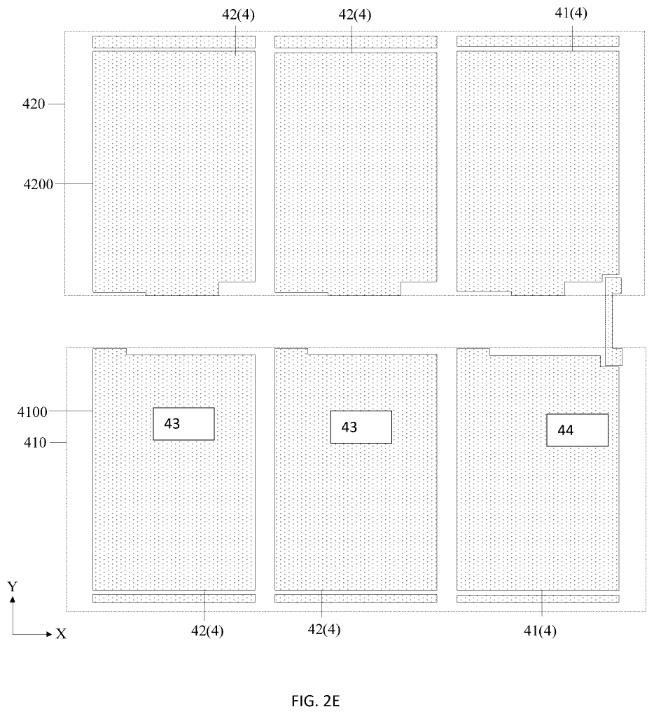

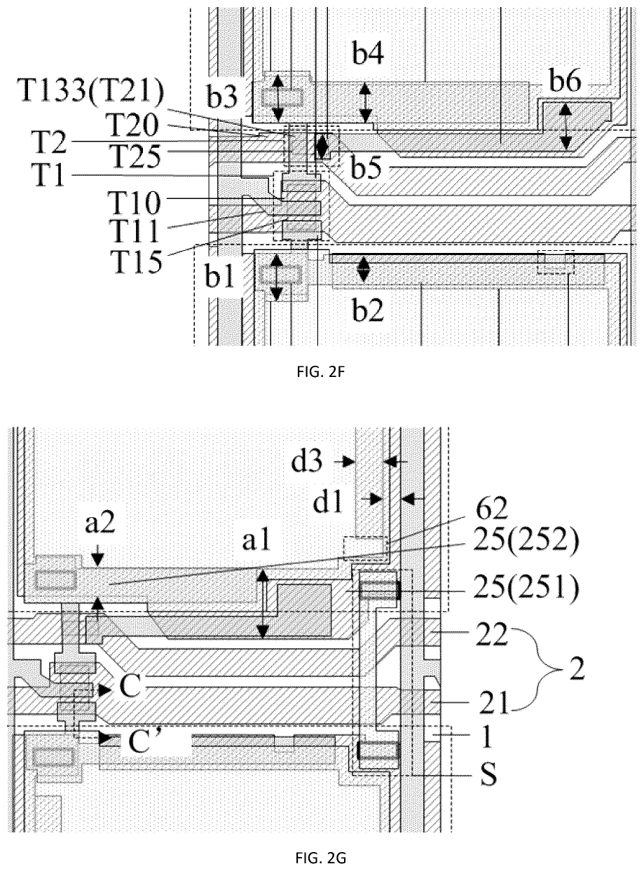

In view of this, the embodiment of the present disclosure provides an array substrate, as shown in FIG. 2A to FIG. 2G. FIG. 2B is a schematic diagram of a single layer of a layer where the gate line group is located in FIG. 2A. FIG. 2C is a schematic diagram of a single layer of an active layer in FIG. 2A. FIG. 2D is a schematic diagram of a single layer of a data line layer in FIG. 2A. FIG. 2E is a schematic diagram of a single layer of a pixel electrode layer in FIG. 2A. FIG. 2F is a magnified schematic diagram of the middle left side of FIG. 2A. FIG. 2G is a magnified schematic diagram of the middle right side in FIG. 2A. The array substrate includes:
a substrate 1;
a plurality of gate line groups 2 on one side of the substrate 1, and the plurality of gate line groups 2 extending along the first direction X;
a plurality of data lines 3 on the same side of the substrate 1 as the gate line groups 2; and the plurality of data lines 3 extend along a second direction Y;
a plurality of pixel electrodes 4 on the same side of the substrate 1 as the gate line groups 2, and in the area formed by the intersection of the gate line groups 2 and the data lines 3, and the plurality of pixel electrodes 4 includes: a first-type pixel electrode 41 and a second-type pixel electrode 42; in some embodiments, the pixel electrodes 4 other than the first-type pixel electrodes 41 can be used as the second-type pixel electrode 42; the first-type pixel electrodes 41 can be the pixel electrodes of blue pixels, and the second-type pixel electrodes 42 can be pixel electrodes of red pixels or green pixels;
a light-shielding portion 5 on the same side of the substrate 1 as the gate line groups 2, and only in the area where the first-type pixel electrode 41 is located; the light-shielding portion 5 includes: a first portion 51 extending along the first direction X; the orthographic projection of the first portion 51 on the substrate 1 passes through the central region of the orthographic projection of the first-type pixel electrode 41 on the substrate 1.

In embodiments of the disclosure, the array substrate includes a light-shielding portion 5, the light-shielding portion 5 includes a first portion 51 extending along the first direction X, the orthographic projection of the first portion 51 on the substrate 1 passes through the central region of the orthographic projection of the first-type pixel electrode 41 on the substrate, a shading of light leakage from the central part of the first-type pixel electrode 41 can be realized, and comparing with the case that the first portion 51 is not arranged with all pixel electrodes 4 or all pixel electrodes 4 are provided with a first portion 51, the proportion of blue light in the color mixing light cannot be reduced. The first portion 51 is only arranged at the position of the first-type pixel electrode 41 in embodiments of the disclosure, so that the transmittance of blue light of the liquid crystal at the side angle of view can be reduced, which can effectively suppress the blueness of the side view screen.

In some embodiments, as shown in FIG. 2A and FIG. 2B, the light-shielding portion 5 further includes: a second portion 52 located on one side of the first portion 51 and extending along the second direction Y. The second portion 52 is connected with one end of the first portion 51, and the orthographic projection of the second portion 52 on the substrate 1 overlaps with the orthographic projection of a side area of the first-type pixel electrode 41 on the substrate 1. Specifically, for example, as shown in FIG. 2A, the second portion 52 starts from the left end of the first portion 51 and extends upwards to shade the upper left side area of the first-type pixel electrode 41 in FIG. 2A. In embodiments of the disclosure, the array substrate includes the second portion 52, so that the light leakage in one side area of the first-type pixel electrode 41 can be avoided, which can further reduce the transmittance of blue light of the liquid crystal in the side view angle of the side area, and the blue bias of the picture in the side view is effectively suppressed.

In some embodiments, as shown in FIG. 2A and FIG. 2B, the light-shielding portion 5 further includes: a third portion 53 on the other side of the first portion 51 and extending along the second direction Y. The third portion 53 is connected with the other end of the first portion 51, and the orthographic projection of the third portion 53 on the substrate 1 overlaps with the orthographic projection of the other side area of the first-type pixel electrode 41 on the substrate 1. For example, in conjunction with FIG. 2A, the third portion 53 starts from the right end of the first portion 51 and extends downwards to shade the lower right side area of the first-type pixel electrode 41 in FIG. 2A. In embodiments of the present disclosure, the array substrate includes a third portion 53 so that the light leakage in the other side area of the first-type pixel electrode 41 can be avoided, which can further reduce the transmittance of blue light of the liquid crystal in the side view angle of the side area, and the blue bias of the picture in the side view is effectively suppressed.

As shown in FIG. 1, in embodiments of the present disclosure, only the position of the dashed circles in FIG. 1 can be shaded, that is, the position of the dashed circles is the position of the color shift when the human eye watches at the left and right directions of the array substrate during the actual use of the array substrate, that is, the color shift position that exists during normal viewing. For the dark line other than the dashed circles, is the color shift position generated when the human eye watches at the up and down directions of the array substrate. Because the probability of the human eye watching the display panel from the up and down directions of the array substrate is reduced, the dark lines at these positions cannot be shaded, so as to avoid reducing the opening ratio of the display panel and simplifying the manufacturing process of the array substrate to reduce the cost of fabricating array substrates.

In some embodiments, the first-type pixel electrode 41 may be a pixel electrode 4 corresponding to the blue color resistor, and the second-type pixel electrode 42 may include a pixel electrode 4 corresponding to the red color resistor, or a pixel electrode 4 corresponding to the green color resistor. In some embodiments, the blue color resistance, red color resistance, and green color resistance can be located on an opposite substrate opposite to the array substrate, so that the display panel emits blue light at the blue color resistance position, red light at the red color resistance, and green light at the green color resistance.

In some embodiments, as shown in FIG. 2A and FIG. 2B, the array substrate further includes: a first signal wiring layer. The light-shielding portion 5 and the first signal wiring layer are on the same layer and include the same material. In some embodiments, the first signal wiring layer can be the common signal wiring layer of the array substrate. In some embodiments, a common electrode layer may be arranged on the opposing substrate opposite to the array substrate, and the signals of the common signal wiring layer of the array substrate and the common electrode layer arranged on the opposing substrate may be the same or different.

In some embodiments, the light-shielding portion 5 and the first signal wiring layer are on the same layer and include the same material, and the first signal wiring layer may be arranged on the layer same as a layer where the gate line groups 2 are located. In this way, the light-shielding portion 5 can be formed at the time same as the time when the gate line groups 2 are formed, and the color shift can be improved while the manufacturing process of the array substrate can be reduced.

In some embodiments, as shown in FIG. 2A and FIG. 2B, the first signal wiring layer further includes: a first common electrode wiring group 230 extending along the second direction Y. The first common electrode wiring group 230 is disconnected at the position of the gate line group 2. The first common electrode wiring group 230 includes: two first common electrode wire 23 extending along the second direction Y on different sides of the data line 3. The light-shielding portion 5 and the first common electrode wire 23 close to the first-type pixel electrode 41 in the first common electrode wiring group 230 are an integrated connection structure.

In some embodiments, as shown in FIG. 2A and FIG. 2B, the width d2 of the second portion 52 in the first direction X is 1\tilde{ }3 times the width d1 of the first common electrode wire 23 in the first direction X. In this way, it can be avoided that if the second portion 52 is set wider, it will have a greater impact on the opening rate of the array substrate, and it can also be avoided that if the second portion 52 is set to be narrower, the light leakage cannot be effectively avoided, and then the color shift cannot be effectively improved.

In some embodiments, as shown in FIG. 2A and FIG. 2B, the width d3 of the third portion 53 in the first direction is approximately equal to the width d2 of the second portion 52 in the first direction X.

In some embodiments, as shown in FIG. 2A and FIG. 2B, the width d4 of the first portion 51 on the second direction Y is approximately equal to the width d2 of the second portion 52 in the first direction X. In the same way, it can be avoided that if the first portion 51 is set wider, it will have a greater impact on the opening rate of the array substrate, and it can also be avoided that if the first portion 51 is set to be narrower, the light leakage cannot be effectively avoided, and then the color shift cannot be effectively improved.

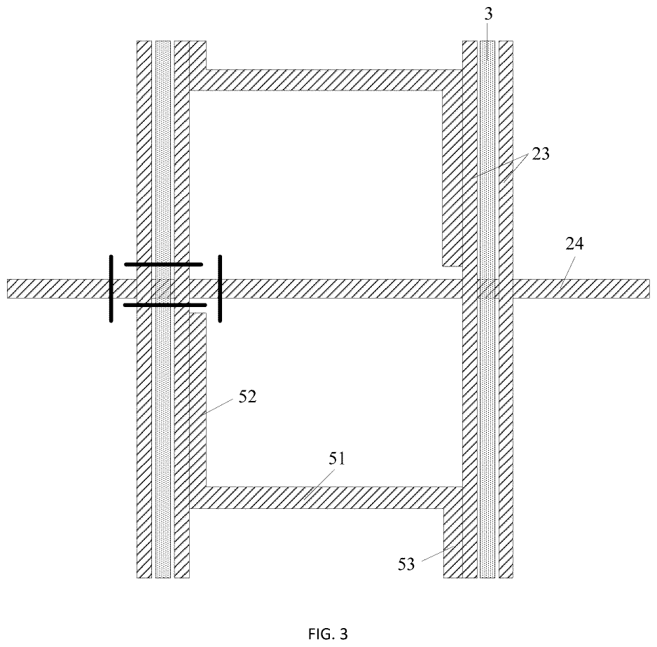

In some embodiments, as shown in FIG. 2A and FIG. 2B, the first signal wiring layer further includes: a second common electrode wire 24 extending along the first direction X. The pixel electrode 4 is provided between the second common electrode wire 24 and the gate line group 2. The second common electrode wires 24 in the same extension direction are an integrated connection structure. There is a gap between the second portion 52 and the second common electrode wire 24. The first common electrode wire 23, the second common electrode wire 24, the second portion 52 form a first notch 61 with an opening facing the side of the first-type pixel electrode 41. In some embodiments, as shown in FIG. 3, when a short circuit occurs at the jumper of the data line 3 and the second common electrode wire 24 due to foreign matter or gate insulation layer rupture, the second common electrode wire 24 and the data line 3 below the jumper need to be cut off at both ends. The second common electrode wire 24 below the jumper is floated, so as to avoid a short circuit due to the data line 3 being in direct contact with the second common electrode wire 24, and the both ends of the data line 3 that are cut off are subsequently connected by bridging. In embodiments of the present disclosure, the first common electrode wire 23, the second common electrode wire 24, and the second portion 52 form the first notch 61 that opens towards one side of the first-type pixel electrode 41, so that the cutting position (as shown by the black thick line in FIG. 3) is narrower in the first direction X, and the problem that the cut-off cannot be achieved at one time during the laser cutting and repair is avoided when the second portion 52 is set to improve the color shift.

In some embodiments, as shown in FIG. 2A and FIG. 2B, each gate line group 2 includes a primary gate line 21 and a secondary gate line 22. The first signal wiring layer further includes a third common electrode wire 25 located on a side of the secondary gate line 22 far away from the mina gate line 21, and extending along the first direction X. There is a pixel electrode 4 between the third common electrode wire 25 and the second common electrode wire 24. The third common electrode wire 25 in the same extension direction is disconnected in the area where the data line 3 is located. There is a gap between the third portion 53 and the third common electrode wire 25. The first common electrode wire 23, the third common electrode wire 25, and the third portion 53 form a second notch 62 that opens towards one side of the pixel electrode 4. In the embodiment of the disclosure, there is a gap between the third portion 53 and the third common electrode wire 25, the first common electrode wire 23, the third common electrode wire 25, and the third portion 53 form a second notch 62 with an opening facing one side of the pixel electrode 4, so that the cutting position is narrower in the first direction X, and the problem that the cut-off cannot be achieved at one time during the laser cutting and repairing is avoided when the third portion 53 is set to improve the color shift.

In some embodiments, as shown in FIG. 2A and FIG. 2B, the third common electrode wire 25 includes: a first subsection 251 and a second subsection 252 located on a side away from the second notch 62, of the first subsection 251. The width a1 of the first subsection 251 in the second direction Y is greater than the width a2 of the second subsection 252 in the second direction Y.

In some embodiments, as shown in FIG. 2A, FIG. 2B and FIG. 2F, the first signal wiring layer further includes: a fourth common electrode wire 26 located on a side of the primary gate line 21 far away from the secondary gate line 22, and extending along the first direction X. There is a pixel electrode 4 between the fourth common electrode wire 26 and the second common electrode wire 24. The fourth common electrode wire 26 in the same extension direction is disconnected in the area where the data line 3 is located. The array substrate further includes: a first transistor T1 connected with the data line 3, and located on one side of the data line 3. The fourth common electrode wire 26 has a notch group 60. The notch group 60 includes: a first notch 64 positioned on one side of the data line 3, and a third notch 63 located on the other side of the same data line 3 and including an opening facing one side of the primary gate line 21. The first notch 64 and the first transistor T1 are located on the same side of the data line 3. In some embodiments, the fourth common electrode wire 26 has the third notch 63, so that when a short occurs at the jumper of the data line 3 and the fourth common electrode wire 26 due to foreign matter or gate insulation layer rupture, the cutting position is narrower in the second direction Y, and the problem that the cut-off cannot be achieved at one time during the laser cutting and repairing. In some embodiments, the length of the first notch 64 in the second direction Y can penetrate through the fourth common electrode wire 26, that is, the first notch is a through hole. Since the first common electrode wire 23 and the second common electrode wire 24 at the periphery of the same pixel electrode 4 have been a connected structure, through which the communication signal can be derived, and the first notch 64 is the through hole, and the cutting can be avoided when a short occurs at the jumper of the data line 3 and the second common electrode wire 24.

In some embodiments, as shown in FIG. 2A and FIG. 2F, each pixel electrode 4 includes: a first pixel electrode row 410 extending along the first direction X and alternately arranged along the second direction Y, and a second pixel electrode row 420. The first pixel electrode row 410 is located on one side of the primary gate line 21 far away from the secondary gate line 22. The second pixel electrode row 420 is located on the side of the secondary gate line 22 far away from the primary gate line 21. The first pixel electrode row 410 includes a plurality of first pixel electrodes 4100, and a second pixel electrode row 420 includes a plurality of second pixel electrodes 4200. In some embodiments, the plurality of first-pixel electrodes 4100 (i.e., the first pixel electrode row 410) may include a first-type pixel electrode 41 (e.g., a blue pixel with a light-shielding portion 5) and a second-type pixel electrode 42 (e.g., a red pixel or a green pixel without a light-shielding portion 5). The plurality of second-pixel electrodes 4200 (i.e., the second pixel electrode row 420) may also include a first-type pixel electrode 41 (e.g., a blue pixel with a light-shielding portion 5) and a second-type pixel electrode 42 (e.g., a red pixel or a green pixel without a light-shielding portion 5). In some embodiments, the pattern shape of the first-type pixel electrode 41 in the first pixel electrode row 410, may be different from the pattern shape of the first-type pixel electrode in the second pixel electrode row 420. The pattern shape of the first-type pixel electrode 41 in the first pixel electrode row 410 may be different from the pattern shape of the second-type pixel electrode 42 in the first pixel electrode row 410. The pattern shape of the first-type of pixel electrode 41 in the second pixel electrode row 420 may be different from the pattern shape of second-type pixel electrode 42 in the second pixel electrode row 420. In some embodiments, in the embodiment of the present disclosure, colors of color resistances corresponding to the pixel electrodes 4 connected to the same data line 3 are the same in the first pixel electrode row 410 and the second pixel electrode row 420 on both sides of the same gate line group 2, that is, for example, as shown in FIG. 2A, colors of the color resistances corresponding to the two pixel electrodes 4 facing each other in up and down direction are the same.

In some embodiments, as shown in FIG. 2A, FIG. 2D and FIG. 2F, the layer where the data line 3 is located further includes: a first electrode T11 of first-transistor electrically connected with the data line 3, and a first electrode portion T12 located on one side of the first electrode T11 of first-transistor, as shown in FIG. 2A, the first electrode portion T12 located on the lower side of the first electrode T11 of first-transistor.

The first electrode portion T12 includes: a second electrode T121 of first-transistor, a first lap portion T122 electrically connected with the second electrode T121 of first-transistor, and a second lap portion T123 extending along the first direction X from one end of the first lap portion T122.

The orthographic projection of the first lap portion T122 on the substrate 1 overlaps with the orthographic projection of the first pixel electrode 4100 on the substrate 1. The first lap portion T122 is electrically connected with the first pixel electrode 4100 through a first through hole K1. The orthographic projection of the second lap portion T123 on the substrate 1 overlaps with the orthographic projection of the fourth common electrode wire 26 on the substrate 1 to form a first capacitor C1.

In some embodiments, as shown in FIG. 2A and FIG. 2D, the maximum width b1 of the first lap portion T122 in the second direction Y is greater than the maximum width b2 of the second lap portion T123 in the second direction Y.

In some embodiments, as shown in FIG. 2A, FIG. 2D and FIG. 2F, the layer where the data line 3 is located further includes: a second electrode portion T13 located on the other side of the first electrode T11 of first-transistor, e.g., a second electrode portion T13 located on the upper side of the first electrode T11 of first-transistor in FIG. 2A.

The second electrode portion T13 includes: a third electrode of the first transistor T131, a third lap portion T132, a first-transistor connection portion T133 connecting the third electrode of the first transistor T131 and the third lap portion T132, and a fourth lap portion T134 extending from one end of the third lap portion T132 along the first direction X.

CLEAN The orthographic projection of the third lap portion T132 on the substrate 1 overlaps with the orthographic projection of the second pixel electrode 4200 on the substrate 1. The third lap portion T132 is electrically connected with the second pixel electrode 4200 through the second through hole K2. The orthographic projection of the fourth lap portion T134 on the substrate 1 overlaps with the orthographic projection of the third common electrode wire 25 on the substrate 1 to form a second capacitor C2.

In some embodiments, as shown in FIG. 2A, FIG. 2D and FIG. 2F, the maximum width b3 of the third lap portion T132 in the second direction Y is greater than the maximum width b4 of the fourth lap portion T134 in the second direction Y.

In some embodiments, as shown in FIG. 2A, FIG. 2D and FIG. 2F, the layer where the data line 3 is located further includes: a third electrode portion T14 located on one side facing the gate line group 2, of the second electrode portion T13.

The third electrode portion T14 includes: a second electrode of the second transistor T141 and a fifth lap portion T142 connected with the second electrode of the second transistor T141. The orthographic projection of the fifth lap portion T142 on the substrate 1 overlaps with the orthotropic projection of the third common electrode wire 25 on the substrate 1 to form the third capacitor C3.

In some embodiments, as shown in FIG. 2A and FIG. 2D, the maximum width b6 of the fifth lap portion T142 in the second direction Y is greater than the maximum width b5 of the second electrode of the second transistor T141 in the second direction Y. In some embodiments, as shown in FIG. 2A, FIG. 2B, FIG. 2C, FIG. 2D and FIG. 2F, the orthographic projection of the fifth lap portion T142 on substrate 1 does not overlap with the orthographic projection of the fourth lap portion T134 on substrate 1.

In some embodiments, as shown in FIG. 2A, FIG. 2B, FIG. 2C and FIG. 2D, the first transistor T1 includes: a control electrode of the first transistor T10, an active layer of the first transistor T15, a first electrode T11 of first-transistor, a second electrode T121 of first-transistor, and a third electrode of the first transistor T131. The control electrode of the first transistor T10 is a part of the primary gate line 21.

In some embodiments, as shown in FIGS. 2A, 2B, 2C, 2D, and 2F, the array substrate further includes a second transistor T2.

The second transistor T2 includes: the control electrode of the second transistor T20, the active layer of the second transistor T25, the first electrode of the second transistor T21, the second electrode of the second transistor T141. The control electrode of the second transistor T20 is a part of the secondary gate line 22, and the first-transistor connection portion T133 is multiplexed as the first electrode of the second transistor T21.

In some embodiments, combined with FIGS. 2A, 2C, and 7, the array substrate further includes an active layer and a passivation layer 12 covered a side away from the substrate 1 of the active layer. The active layer includes the active layer of the first transistor T15, and the active layer of the second transistor T25. The material of the active layer includes indium gallium zinc oxide, and a material of the passivation layer 12 includes silicon dioxide and silicon nitride.

In some embodiments, as shown in FIG. 7, the active layer (including the first active layer T15) is located on a side of the primary gate line 21 facing away from the substrate 1. The layer where the data line 3 is located (including the first electrode T11 of first-transistor) is located on a side of the active layer (including the first active layer T15) facing away from the primary gate line 21. The pixel electrode 4 is located on a side facing away from the active layer, of the layer (including the first electrode T11 of first-transistor) where the data line 3 is located. The array substrate further includes a gate insulation layer 11 located between the active layer (including the first active layer T15) and the primary gate line 21, and a planarization layer 13 located on a side of the passivation layer 12 facing away from the substrate 1, and a first alignment film layer 14 located on a side of the pixel electrode 4 facing away from the substrate 1.

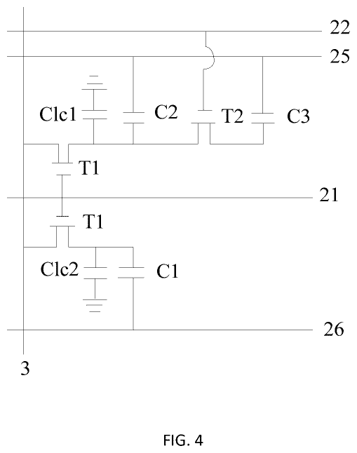

In some embodiments, as shown in FIG. 4, FIG. 4 can be the equivalent circuit diagram corresponding to the upper and lower pixel electrodes 4 in FIG. 2A, the circuit includes: the first transistor T1, the second transistor T2, the first capacitor C1, the second capacitor C2, the third capacitor C3, the first liquid crystal capacitor Clc1, the second liquid crystal capacitor Clc2.

The control electrode T10 of the first transistor T1 is electrically connected with the primary gate line 21, the first electrode T11 of the first transistor T1 is electrically connected with the data line 3, the second electrode T121 of the first transistor T1 is electrically connected with one end of the first capacitor C1, and the third electrode T131 of the first transistor T1 is electrically connected with one end of the second capacitor C2.

The control electrode of T20 of the second transistor T2 is electrically connected with the secondary gate line 22, the first electrode T21 of the second transistor T2 is electrically connected with the third electrode T131 of the first transistor T1, and the second electrode T141 of the second transistor is electrically connected with one end of the third capacitor C3.

The other end of the first capacitor C1 is electrically connected with the fourth common electrode wire 26. The other end of the second capacitor C2 is electrically connected with the third common electrode wire 25. The other end of the third capacitor C3 is electrically connected with the third common electrode wire 25. The first pixel electrode 4100 and the common electrode of the opposite substrate form the first liquid crystal capacitance Clc1. The second pixel electrode 4200 and the common electrode of the opposite substrate form the second liquid crystal capacitance Clc2.

In some embodiments, the array substrate may further include a plurality of cascaded gate drive units, the nth primary gate line 21 can be electrically connected with the nth-level gate drive unit to transmit the gate signal output by the nth-level gate drive unit. The secondary gate line 22 can be electrically connected with the (n+m)th-level gate drive unit, that is, the (n+m)th-level gate drive unit is electrically connected with the (n+m)th row of primary gate line 21, and is also electrically connected with the n-th row of secondary gate line 22 so as to provide a gate signal to (n+m)th row of primary gate line 21, while providing the gate signal to the nth row of secondary gate line 22, to turn on (n+m)th row of the first transistor T1 while turning on nth row of the second transistor T2, so that the second pixel electrode 4200 in the nth row (in some embodiments, the pixel electrodes 4 on the upper and lower sides of a gate line group 2 can be used as a pixel electrode row, that is, a pixel electrode row can include: the first pixel electrode line 410 and the second pixel electrode line 420; the nth row of second pixel electrode 4200 can be understood as the second pixel electrode 4200 of the second pixel electrode line 420 in the nth pixel electrode row) achieves voltage division through the third capacitance C3 conducted by the second transistor T2, so that the electrode voltage of the second pixel electrode 4200 is lower than the electrode voltage of the first pixel electrode 4100, therefore, the luminous brightness of the second pixel electrode 4200 is less than the luminous brightness of the first pixel electrode 4100, so that the second pixel electrode row 420 is a dark pixel electrode row, and the first pixel electrode row 410 is a bright pixel electrode row, so that the pixels of the same luminous color have more brightness ladders, and the color shift problem of the liquid crystal display panel can be improved.

In some embodiments, m≥1, m=6, for example, when n=1, m=6, that is, the 7th level gate driver unit is electrically connected with the 7th row of primary gate line 21, and also electrically connected with the 1st row of secondary gate line 22 to provide a gate signal to the 7th row of primary gate line 21, and at the same time provide a gate signal to the 1st row of the secondary gate line 22, so that when the 7th row of the first transistor T1 is turned on, the 1st row of the second transistor T2 is also turned on at the same time, so that the luminous brightness of the second pixel electrode 4200 in the first row is reduced.

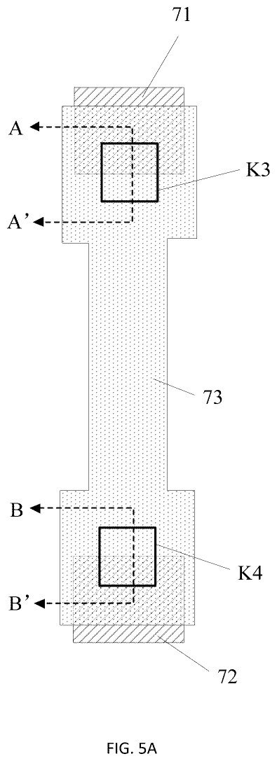

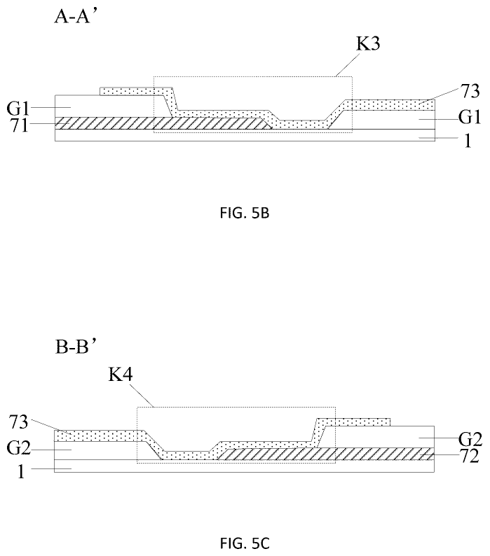

In some embodiments, see FIG. 5A, FIG. 5B, FIG. 5C shows, FIG. 5B is a cross-sectional schematic diagram along the dashed line AA′ in FIG. 5A. FIG. 5C is a schematic cross-section along the dashed line BB′ in FIG. 5A. The array substrate further includes: a first wiring 71, a second wiring 72, and an adapter portion 73.

There is a first insulating layer G1 between the adapter portion 73 and the first wire 71. The first insulating layer G1 is provided with a third hole K3. The third through hole K3 exposes parts of the first wiring 71 and the exposes parts of the substrate 1.

There is a second insulating layer G2 is provided between the adapter portion 73 and the second wiring 72. The second insulating layer G2 is provided with a fourth through hole K4. The fourth through hole K4 exposes parts of the second wiring 72, and exposes parts of the substrate 1.

One end of the adapter portion 73 covers the third hole K3, and contacts with the first wiring 71 through the third hole K3, the other end covers the fourth through hole K4, contacts with the second wiring 72 through the fourth through hole K4, and laps the first wiring 71 with the second wiring 72.

In the conventional design, when the first alignment film layer 14 is formed, the alignment liquid flow passes through a full hanging hole with a small through-hole size (for example, less than or equal to 8 μm*8 μm), and deeper hole depth, due to the liquid tension of the alignment liquid, the fluidity of the alignment liquid is poor, and the alignment liquid above the through hole cannot flow in normally, and the alignment liquid does not stick, and a similar halo occurs around the through hole, and the macroscopic manifestation is moire pattern on the screen. In the embodiment of the disclosure, when the first wiring 71 and the second wiring 72 are lapped and electrically connected, the original full hanging hole is optimized into a semi-hanging hole design, and the third hole K3 and the fourth through hole K4 are designed as semi-through hole designs (i.e., for example, the third hole K3 exposes parts of the first wiring 71, and exposes parts of the substrate 1), so that the third hole K3 and the fourth through hole K4 form an inner step structure, which has the technical effect of draining the alignment liquid, preventing the alignment liquid from sticking and avoiding the moire pattern phenomenon in the screen.

In some embodiments, the first wiring 71 may include: the primary gate line 21, the secondary grid 22, the data line 3, the first common electrode wire 23, the second common electrode wire 24, the third common electrode wire 25 or the fourth common electrode wire 26.

The second wiring 72 may include: the primary gate line 21, the secondary gate line 22, the data line 3, the first common electrode wire 23, the second common electrode wire 24, the third common electrode wire 25 or the fourth common electrode wire 26.

In some embodiments, the adapter portion 73 and the pixel electrode 4 are on the same layer and of the same material.

In some embodiments, as shown in FIG. 7, the first insulating layer G1 may include: a gate insulating layer 11, a passivation layer 12 and/or a planarization layer 13. The second insulating layer G2 includes: an insulating layer 11, a passivation layer 12 and/or a planarization layer 13.

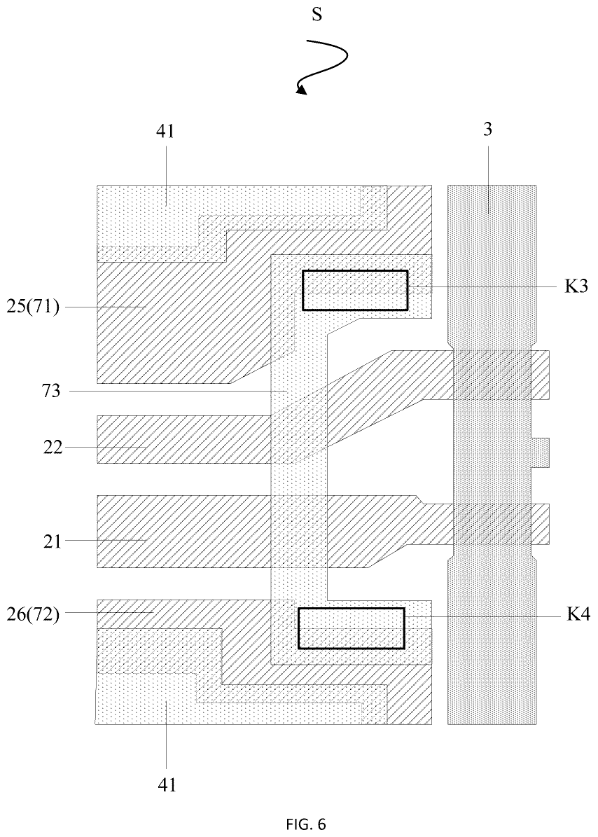

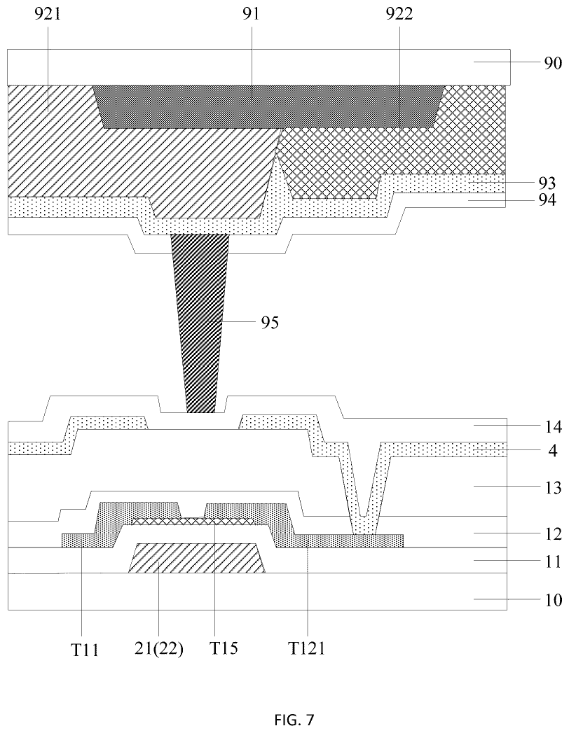

In some embodiments, for example, as shown in FIG. 6, FIG. 6 is an enlarged schematic diagram at the dashed circle S in FIG. 2A, that is, the first wiring is a third common electrode wire 25 above the gate line group 2, the second wiring 72 is a fourth common electrode wire 26 below the gate line group 2. The third common electrode wire 25 on the upper side of the gate line group 2 is electrically connected through an adapter portion 73. The third through hole K3 connecting the adapter portion 73 and the third common electrode wire 25 on the upper side of the gate line group 2 is a semi-through hole. The fourth through hole K4 connecting the adapter portion 73 and the fourth common electrode wire 26 on the lower side of the gate line group 2 is a semi-through hole design.

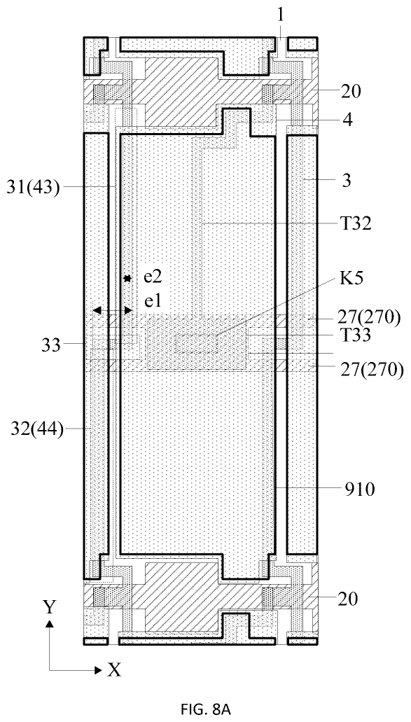

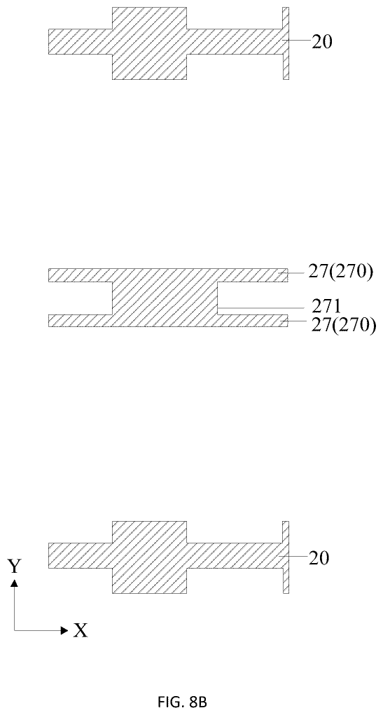

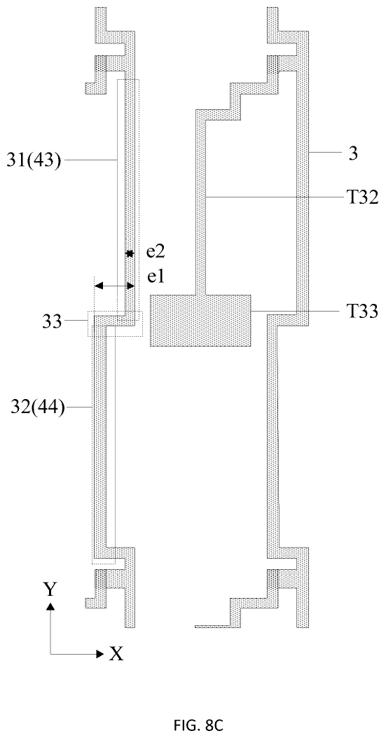

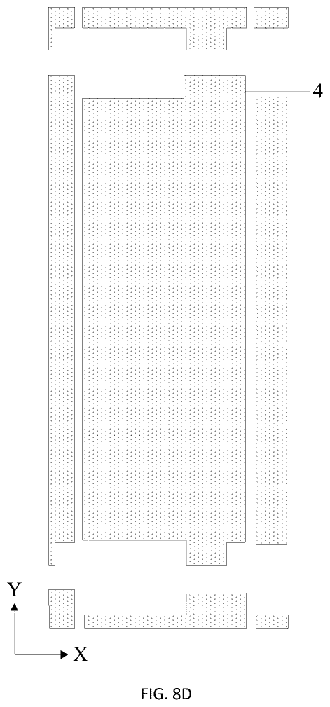

Based on the same invention idea, embodiments of the present disclosure further provide an array substrate, as shown in FIG. 8A to FIG. 8D, FIG. 8B is a schematic diagram of a single layer of the gate line 20 in FIG. 8A. FIG. 8C is a schematic diagram of a single layer of the data line in FIG. 8A. FIG. 8D is a schematic diagram of a single layer of the pixel electrode in FIG. 8A. The array substrate includes:
a substrate 1;
a plurality of gate lines 20 on a side of the substrate 1, and extending along the first direction X;
a plurality of data lines 3 on the same side of the substrate 1 as the gate line 20, and extending along the second direction;
a plurality of pixel electrodes 4 on the same side of the substrate 1 as the gate line 20 and in the areas formed by the intersection of the gate lines 20 and the data lines 3.

Each data line 3 includes a first data portion 31 extending along the second direction Y, a second data portion 32 extending along the second direction Y, and a third data portion 33 extending along the first direction X and connecting the first data portion 31 with the second data portion 32. The extension line of the first data portion 31 does not overlap with the extension line of the second data portion 32. The orthographic projection of the extension line of the third data portion 33 passes through the central area of the orthographic projection of the pixel electrode 4 on the substrate 1. The orthographic projection of the first data portion 31 on the substrate 1 overlaps with the orthographic projection of the first side area 43 of the pixel electrode 4 on the substrate 1. The orthographic projection of the second data portion 32 on the substrate 1 overlaps with the orthographic projection of the second side area 44 of the pixel electrode 4 on the substrate 1.

In embodiments of the disclosure, the data line 3 includes a first data portion 31 extending along the second direction Y, a second data portion 32 extending along the second direction Y, and a third data portion 33 extending along the first direction X and connecting the first data portion 31 with the second data portion 32, so that the first side area 43 and the second side area 44 of the pixel electrode 4 can be shielded from light leakage.

In some embodiments, as shown in FIG. 8A and FIG. 8C, the length e1 of the third data portion 33 on the first direction X is 2-4 times the width e2 of the first data portion 31 on the first direction X.

In some embodiments, as shown in FIG. 8A and FIG. 8C, the array substrate further includes: a transistor second electrode T32 on a layer same as the layer where the data line 3 is located and a first electrode block T33 connected with the transistor second electrode T32.

The first electrode block T33 is located at a position between two adjacent third data portions 33. The orthographic projection of the first electrode block T33 on the substrate 1 overlaps with the orthographic projection of the pixel electrode 4 on the substrate 1. The first electrode block T33 is electrically connected with the pixel electrode 4 through the fifth through hole K5.

In some embodiments, as shown in FIG. 8A and FIG. 8B, the array substrate further includes: a fifth common electrode wiring group 270. The fifth common electrode wiring group 270 includes two fifth common electrode wirings 27 extending along the first direction X.

A second electrode block 271 is provided between two fifth common electrode wirings 27 in the same fifth common electrode wiring group 270. The orthotropic projection of the second electrode block 271 on the substrate 1 overlaps with the orthographic projection of the first common electrode block T33 on the substrate 1 to form a fourth capacitor C4.

Based on the same invention conception, embodiments of the disclosure further provide a display panel including the array substrate provided as embodiments of the present disclosure.

In some embodiments, as shown in FIG. 7, the display panel further includes an opposite substrate opposite to the array substrate. The opposite substrate is provided with a common electrode layer 93. In some embodiments, the opposite substrate may include an opposing substrate 90, a black matrix layer 91 arranged between the opposing substrate 90 and the common electrode layer 93, a color resistance layer. The color resistance layer may include a blue color resistance 921, a red color resistance 922, and a green color resistance. A second alignment film layer 94 may also be arranged on a side of the common electrode layer 93 facing away from the opposing substrate 90. In some embodiments, as shown in FIG. 8A, the black matrix layer 91 may include a black matrix opening 910.

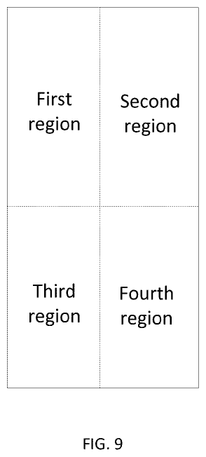

In some embodiments, the display panel further includes a liquid crystal layer arranged between the array substrate and the opposite substrate. The liquid crystal layer has four liquid crystal regions in the area where the pixel electrodes 4 are located. The liquid crystal orientations in the liquid crystal regions are different. In some embodiments, as shown in FIG. 9, for example, the liquid crystal layer has four liquid crystal regions in the area where the pixel electrodes 4 are located, which are the first region, the second region, the third region, the fourth region. The orientations of the liquid crystal corresponding to the first region, the second region, the third region, the fourth region are different. In some embodiments, the orientations of the four liquid crystal regions corresponding to one pixel electrode are different, which can be achieved by irradiating the first alignment film layer and the second alignment film with ultraviolet light or other methods to achieve different orientations. For example, the region of the first alignment film corresponding to one pixel electrode is divided into left and right parts along the direction of the data line, the alignment directions of the left and right parts are parallel, and are opposite to each other. The region of the second alignment film corresponding to the one pixel electrode is divided into upper and lower parts along the gate line extension direction, the alignment directions of the upper and lower parts are parallel, and are opposite to each other. The alignment directions of the first alignment film layer and the second alignment film layer are perpendicular to each other, which eventually form four distinct alignment regions.

Based on the same invention conception, embodiments of the present disclosure further provide a display device, which includes a display panel provided in embodiments of the present disclosure. The display device can be: mobile phones, tablet computers, televisions, monitors, laptops, digital photo frames, navigators, smart watches, fitness wristbands, personal digital assistants and any other products or components with display functions. The other indispensable components of the display device are those of ordinary skill in the art that should be understood, and are not repeated herein, nor should they be used as a limitation on the present invention. In addition, because the principle of the display device to solve the problem is similar to the principle of the display panel to solve the problem, the embodiment of the display device can refer to the embodiment of the liquid crystal display panel described above, and the repetition will be omitted.

Although preferred embodiments of the present invention have been described, those embodiments may be subject to additional changes and modifications once the basic inventive concepts are known to those skilled in the art. Therefore, the attached claims are intended to be construed to include the preferred embodiments and all changes and modifications that fall within the scope of the invention.

Obviously, a person skilled in the art may make various changes and variants to the embodiments of the present invention without departing from the spirit and scope of the embodiments of the present invention. Thus, if these modifications and variants of the embodiments of the present invention fall within the scope of the claims of the present invention and their equivalents, the present invention is also intended to include these modifications and variants.

1-36. (canceled)

37. An array substrate, comprising:
a substrate;
a plurality of gate line groups on a side of the substrate, wherein the plurality of gate line groups extend along a first direction;
a plurality of data lines on the same side of the substrate as the gate line groups; wherein the plurality of data lines extend along a second direction;
a plurality of pixel electrodes on the same side of the substrate as the gate line groups and in an area formed by an intersection of the gate line groups and the data lines, wherein the plurality of pixel electrodes comprises: a first-type pixel electrode and a second-type pixel electrode;
a light-shielding portion on the same side of the substrate as the gate line groups and only in an area where the first-type pixel electrode is located; wherein the light-shielding portion comprises: a first portion extending in the first direction; an orthographic projection of the first portion on the substrate passes through a central area of an orthographic projection of the first-type pixel electrode on the substrate.

38. The array substrate of claim 37, wherein the light-shielding portion further comprises: a second portion that is on a side of the first portion and extends along the second direction;
the second portion is connected with one end of the first portion, and an orthotropic projection of the second portion on the substrate overlaps with an orthographic projection of a side area of the first-type of pixel electrode on the substrate.

39. The array substrate of claim 37, wherein the light-shielding portion further comprises: a third portion that is on the other side of the first portion and extends along the second direction;
the third portion is connected with the other end of the first portion, and an orthotropic projection of the third portion on the substrate overlaps with an orthographic projection of the other side area of the first-type pixel electrode on the substrate.

40. The array substrate of claim 37, wherein the first-type pixel electrode is a pixel electrode corresponding to a blue color resistance, and the second-type of pixel electrode comprises a pixel electrode corresponding to a red color resistance, or a pixel electrode corresponding to a green color resistance.

41. The array substrate of claim 39, further comprises: a first signal wiring layer, wherein the light-shielding portion and the first signal wiring layer are on a same layer and of a same material;
wherein the first signal wiring layer further comprises: a first common electrode wiring group extending along the second direction, wherein the first common electrode wiring group is disconnected at the gate line groups;
the first common electrode wiring group comprises: two first common electrode wires extending along the second direction at different sides of each data line, and the light-shielding portion and the first common electrode wire close to the first-type pixel electrode in the first common electrode wiring group are integrated connection structure.

42. The array substrate of claim 41, wherein the first signal wiring layer further comprises: a second common electrode wire extending along the first direction; a pixel electrode is provided between the second common electrode wire and the gate line group, and the second common electrode wire in a same extension direction is an integrated connection structure;
there is a gap between the second portion and the second common electrode wire; and the first common electrode wire, the second common electrode wire, and the second portion form a first notch with an opening facing a side of the first-type pixel electrode.

43. The array substrate of claim 42, wherein each gate line group comprises: a primary gate line and a secondary gate line;
the first signal wiring layer further comprises: a third common electrode wire that is arranged at a side of the secondary gate line far away from the primary gate line, and extends along the first direction;
there is the pixel electrode between the third common electrode wire and the second common electrode wire, and the third common electrode wire in a same extension direction is disconnected in an area where the data line is located;
there is a gap between the third portion and the third common electrode wire; and the first common electrode wire, the third common electrode wire, and the third portion form a second notch with an opening facing a side of the pixel electrode.

44. The array substrate of claim 43, wherein the third common electrode wire comprises: a first subsection and a second subsection located on a side of the first subsection far away from the second notch;
a width of the first subsection in the second direction is greater than a width of the second subsection in the second direction.

45. The array substrate of claim 43, wherein the first signal wiring layer further comprises: a fourth common electrode wire that is arranged on a side of the primary gate line far away from the secondary gate line, and extends along the first direction;
there is the pixel electrode between the fourth common electrode wire and the second common electrode wire, and the fourth common electrode wire in a same extension direction is disconnected in an area where the data line is located;
the array substrate further comprises: a first transistor connected with the data line and arranged on a side of the data line;
the fourth common electrode wire comprises a notch group, the notch group comprises: a first notch located on a side of one data line, and a third notch located on the other side of the one data line and comprising an opening facing a side of the primary gate line, and the first notch and the first transistor are located on a same side of the one data line.

46. The array substrate of claim 45, wherein the plurality of pixel electrodes comprise: a first pixel electrode row and a second pixel electrode row which extend along the first direction and are alternately arranged along the second direction;
the first pixel electrode row is arranged on a side of the primary gate line far away from the secondary gate line, and the second pixel electrode row is arranged on a side of the secondary gate line far away from the primary gate line;
the first pixel electrode row comprises a plurality of first pixel electrodes, and the second pixel electrode row comprises a plurality of second pixel electrodes.

47. The array substrate of claim 46, wherein a layer where the data line is located further comprises: a first electrode of the first transistor electrically connected with the data line, and a first electrode portion arranged on a side of the first electrode of the first transistor;
the first electrode portion comprises: a second electrode of the first transistor, a first lap portion electrically connected with the second electrode of the first transistor, and a second lap portion extending along the first direction from one end of the first lap portion;
an orthographic projection of the first lap portion on the substrate overlaps with an orthographic projection of the first pixel electrode on the substrate, the first lap portion is electrically connected with the first pixel electrode through a first through hole, and an orthotropic projection of the second lap portion on the substrate overlaps with an orthographic projection of the fourth common electrode wire on the substrate to form a first capacitance;
wherein the layer where the data line is located further comprises: a second electrode portion arranged on the other side of the first electrode of the first transistor;
the second electrode portion comprises: a third electrode of the first transistor, a third lap portion, a first-transistor connection portion connecting the third electrode of the first transistor and the third lap portion, and a fourth lap portion extending along the first direction from one end of the third lap portion;
an orthographic projection of the third lap portion on the substrate overlaps with an orthotropic projection of the second pixel electrode on the substrate, the third lap portion is electrically connected with the second pixel electrode through a second through hole; an orthotropic projection of the fourth lap portion on the substrate overlaps with an orthographic projection of the third common electrode wire on the substrate to form a second capacitance;
wherein the layer where the data line is located further comprises: a third electrode portion arranged on a side of the second electrode portion facing the gate line group;
the third electrode portion comprises: a second electrode of the second transistor and a fifth lap portion connected with the second electrode of the second transistor; an orthographic projection of the fifth lap portion on the substrate overlaps with the orthographic projection of the third common electrode wire on the substrate to form a third capacitance.

48. The array substrate of claim 47, wherein a maximum width of the first lap portion in the second direction is greater than a maximum width of the second lap portion in the second direction;
a maximum width of the third lap portion in the second direction is greater than a maximum width of the fourth lap portion in the second direction; and
a maximum width of the fifth lap part in the second direction is greater than a maximum width of the second electrode of the second transistor in the second direction.

49. The array substrate of claim 47, wherein the orthographic projection of the fifth lap portion on the substrate does not overlap with the orthographic projection of the fourth lap portion on the substrate.

50. The array substrate of claim 47, wherein the first transistor comprises: a control electrode of the first transistor, an active layer of the first transistor, the first electrode of the first transistor, the second electrode of the first transistor and the third electrode of the first transistor; wherein the control electrode of the first transistor is a portion of the primary gate line;
wherein the array substrate further comprises: a second transistor;
the second transistor comprises: a control electrode of the second transistor, an active layer of the second transistor, a first electrode of the second transistor, the second electrode of the second transistor; wherein the control electrode of the second transistor is a portion of the secondary gate line, the first-transistor connection portion is multiplexed as the first electrode of the second transistor.

51. The array substrate of claim 45, further comprises: a first wiring, a second wiring, and an adapter portion;
there is a first insulating layer between the adapter portion and the first wiring, the first insulating layer comprises a third through hole; the third through hole exposes a part of the first wiring, and exposes a part of the substrate;
there is a second insulating layer between the adapter portion and the second wiring, the second insulating layer comprises a fourth through hole; the fourth through hole exposes a part of the second wiring, and exposes a part of the substrate;
one end of the adapter portion covers the third through hole, and contacts with the first wiring through the third through hole; the other end of the adapter portion covers the fourth through hole, and contacts with the second wiring through the fourth through hole; the adapter portion laps the first wiring with the second wiring;
wherein the first wirings comprise the primary gate line, the secondary gate line, the data line, the first common electrode wire, the second common electrode wire, the third common electrode wire or the fourth common electrode wire;
the second wire trace comprises: the primary gate line, the secondary gate line, the data line, the first common electrode wire, the second common electrode wire, the third common electrode wire or the fourth common electrode wire.

52. An array substrate, comprising:
a substrate;
a plurality of gate lines on a side of the substrate, and extending in a first direction;
a plurality of data lines on the same side of the substrate as the gate lines, and extending along a second direction;
a plurality of pixel electrodes on the same side of the substrate as the gate lines, and in areas formed by an intersection of the gate lines and the data lines;
wherein each data line comprises a first data portion extending in the second direction, a second data portion extending in the second direction, and a third data portion extending along the first direction and connecting the first data portion with the second data portion;
an extension line of the first data portion does not overlaps with an extension line of the second data portion;
an orthographic projection of an extension line of the third data portion on the substrate passes through a central area of an orthographic projection of the pixel electrode on the substrate;
an orthographic projection of the first data portion on the substrate overlaps with an orthographic projection of a first side area of the pixel electrode on the substrate; an orthotropic projection of the second data portion on the substrate overlaps with an orthographic projection of a second side area of the pixel electrode on the substrate.

53. The array substrate of claim 52, further comprises: a second electrode of a transistor in a layer same as a layer where the data lines are located, and a first electrode block connected with the second electrode of the transistor;
the first electrode block is arranged at a position between two adjacent third data portions; an orthographic projection of the first electrode block on the substrate overlaps with the orthographic projection of the pixel electrode on the substrate, and the first electrode block is electrically connected with the pixel electrode through a fifth through hole;
wherein the array substrate further comprises: a fifth common electrode wiring group; the fifth common electrode group comprises: two fifth common electrode wire extending along the first direction;
a second electrode block is provided between two fifth common electrode wires in a same fifth common electrode wiring group, and an orthotropic projection of the second electrode block on the substrate overlaps with an orthotropic projection of the first common electrode block on the substrate to form a fourth capacitance.

54. A display panel, comprising the array substrate of claim 37.

55. The display panel of claim 54, further comprises: an opposing substrate opposite to the array substrate, wherein the opposing substrate is provided with a common electrode layer;
wherein the display panel further comprises a liquid crystal layer arranged between the array substrate and the opposing substrate; the liquid crystal layer comprises four liquid crystal regions in an area where the pixel electrodes are located, and liquid crystal orientations in the liquid crystal regions are different.

56. A display device, comprising the display panel of claim 54.
